(19) United States
(12) Patent Application Publication
(10) Pub. No.: US 2006/0285565 A1
(43) Pub. Date: Dec. 21, 2006

(54) Structure of laser and method of manufacturing the same

(75) Inventors: Wei Chang, Taipei City (TW); Tsung-Wei Lin, Yilan Hsien (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/155,721

(22) Filed: Jun. 20, 2005

(51) Int. Cl. H01S 5/00; H01S 3/04

(52) U.S. Cl. 372/43.01

(57) ABSTRACT

A structure of laser and manufacture methods thereof are disclosed. The method comprises the steps of: 1. coupling a plurality of photo diodes with first pins of a plurality of pin groups on a frame; 2. mounting a plurality of laser diodes on the photo diodes; 3. bonding the laser diodes and the photo diodes to the second and third pins of the pin groups by conducting wires; 4. spreading a plurality of adhesive layers on the photo diodes to form a plurality of convex lenses for collecting the laser light; 5. covering the pin groups on which the bonding and spreading steps are performed with a plurality of casings, each having an opening, a notch, and a mounting chamber; and 6. cutting off connected portions of the pins to obtain a plurality of lasers. Consequently, this manufacture method is suitable for mass production to obtain numerous lasers. Besides, the manufacture method of the present invention can significantly reduce the production cost and increase the value of monitor current (Im).

### FIELD OF THE INVENTION

The present invention relates to a structure of laser or the like and the manufacture method thereof for increasing the value of monitor. current (Im), protecting conducting wires, and increasing the credibility.

### BACKGROUND OF THE INVENTION

Referring to FIG. 1 and FIG. 2 simultaneously, the conventional laser is composed of three thick metals 21, 22, and 23. The metal 21 comprises a low platform 211. A laser diode 25 is mounted on the thick metal 21. For the purpose of light feedback, the photo diode 26 is mounted on the low platform 211 of the thick metal 21 to receive the light, which is emitted form the rear end of the laser diode 25.

The laser diode 25 has a bottom electrode for contacting and coupling with the thick metal 21. Besides, the laser diode 25 also has a top electrode, wherein the top electrode is connected with the thick metal 22 by a conducting wire 27. The photo diode 26 has a bottom electrode for contacting and coupling with the thick metal 21. Besides, the photo diode 26 also has a top electrode, wherein the top electrode is connected to the thick metal 23 by a conducting wire 28.

The above-mentioned devices, which are formed on the three metals 21, 22, and 23, are covered with an adhesive layer 29 for exposing the front end of the laser diode 25 such that the greatest intensity light F, which is emitted from the front end of the laser diode 25, is not covered with the adhesive layer 29. The light B is emitted from the rear end of the laser diode 25 to the photo diode 26 to enable the photo diode 26 to measure the light intensity at the rear end of the laser diode 25.

The feedback of the monitor current (Im) is very important for the laser diode. However, the manufacture process of the above-mentioned laser is very complicated, and the photo diode is a plane type diode. Because the laser diode is provided with small light emitting angle, the photo diode is still unable to receive the feedback light from the laser diode even if the photo diode is coupled with the metal platform having a drop height.

Consequently, the present invention provides a method of manufacturing the laser for mass production and simplifying the manufacture process. Besides, the manufacture method of the present invention can increase the value of monitor current (Im), protect the conducting wires, and increase the credibility.

### SUMMARY OF THE INVENTION

It is a main object of the present invention to provide a manufacture method for the laser to simplify the manufacture process and reduce the production cost.

It is another object of the present invention to provide a manufacture method of the laser, which is suitable for mass production.

It is a further object of the present invention to provide a structure of laser to increase the value of monitor current (Im) and protect the conducting wires for further increasing the credibility of the laser.

In order to achieve the aforementioned object, the manufacture method of the present invention comprises the steps of: 1. coupling a plurality of photo diodes with first pins of a plurality of pin groups on a frame; 2. mounting a plurality of laser diodes on the photo diodes; 3. bonding the laser diodes and the photo diodes to the second and third pins of the pin groups by conducting wires; 4. spreading a plurality of adhesive layers on the photo diodes to form a plurality of convex lenses for collecting the laser light; 5. covering the pin groups on which the bonding and spreading steps are performed with a plurality of casings, each having an opening, a notch, and a mounting chamber; and 6. cutting off connected portions of the pins to obtain a plurality of lasers.

Consequently, this manufacture method is suitable for mass production to obtain numerous lasers. Besides, the manufacture method of the present invention can significantly reduce the production cost, protect the conducting wires, and increase the value of monitor current (Im).

The aforementioned aspects and advantages of the present invention will be readily clarified in the description of the preferred embodiments and the enclosed drawings of the present invention.

### BRIEF DESCRIPTION OF THE DRAWINGS

FIG. 1 is a top view showing a conventional laser.

FIG. 2 is a cross-sectional view showing the conventional laser.

FIG. 3 shows a manufacture process of the present invention.

FIG. 4 is a schematic view showing that two diodes are coupled with a frame in accordance with the present invention.

FIG. 5 is a schematic view showing that the frame is covered with a casing in accordance with the present invention.

FIG. 6 is a cross-sectional view of the present invention.

FIG. 7 shows another manufacture process of the present invention.

### DETAILED DESCRIPTION OF THE PREFERRED EMBODIMENT

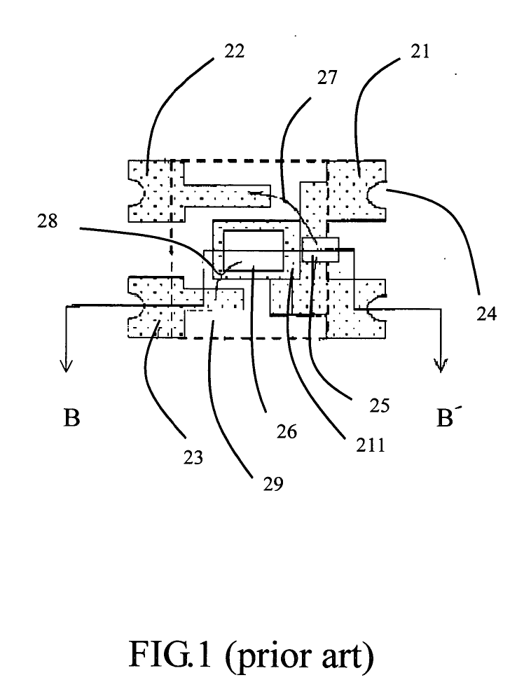

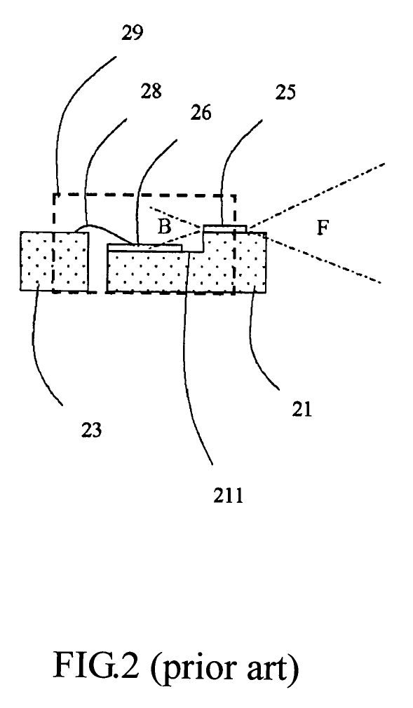

FIG. 1 and FIG. 2 show a top view and a cross-sectional view of the conventional laser. This conventional structure is described above, and its related description is omitted herein.

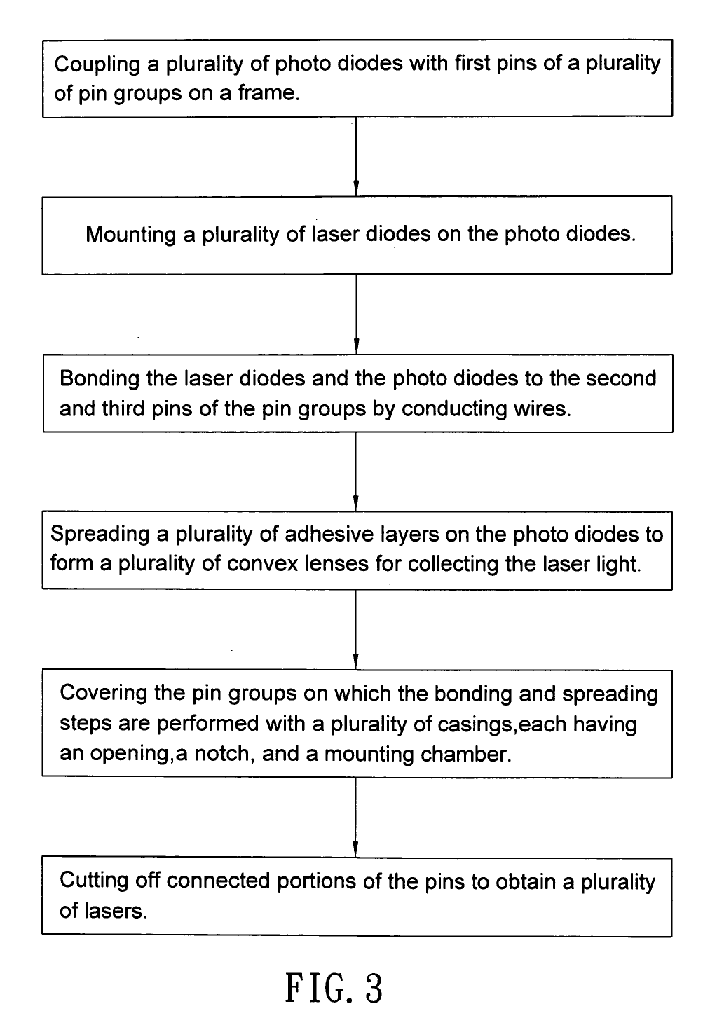

Referring to FIG. 3, a manufacture process of the present invention comprises the steps of:

1. coupling a plurality of photo diodes with first pins of a plurality of pin groups on a frame;

2. mounting a plurality of laser diodes on the photo diodes;

3. bonding the laser diodes and the photo diodes to the second and third pins of the pin groups by conducting wires;

4. spreading a plurality of adhesive layers on the photo diodes to form a plurality of convex lenses for collecting the laser light;

5. covering the pin groups on which the bonding and spreading steps are performed with a plurality of casings, each having an opening, a notch, and a mounting chamber; and

6. cutting off connected portions of the pins to obtain a plurality of lasers.

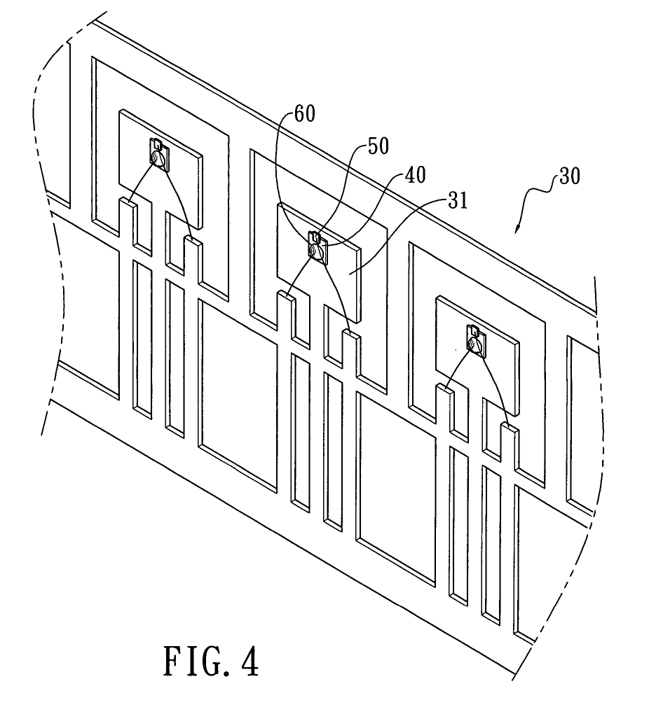

Because of having identical structure the manufacture process of a single laser is illustrated for simplifying the description. In the practical manufacture process, a photo diode 40 is coupled with a first pin of a pin group on a frame 30. Referring to FIG. 4, in this preferred embodiment, the pin group is composed of three connected pins, wherein the middle pin comprises a large area connection part 31 on the top. The photo diode 40 is adhered to the large area connection part 31. Next, the laser diode 50 is mounted on the photo diode 40 by adhesion. Thereafter, the laser diode and the photo diode are bonded to the second and third pins of the pin group by conducting wires.

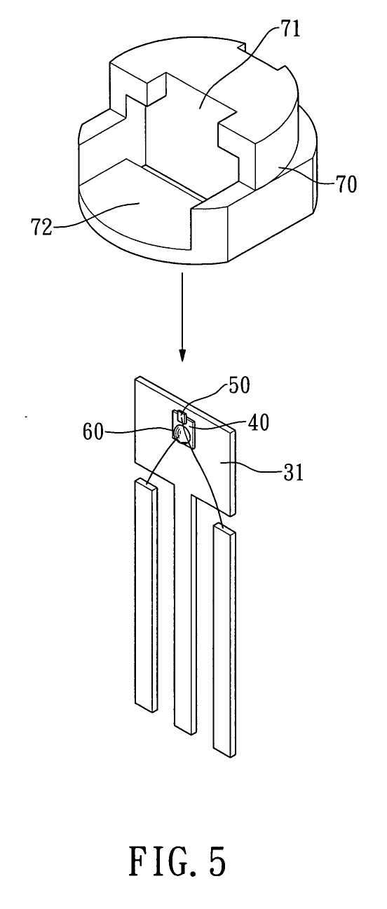

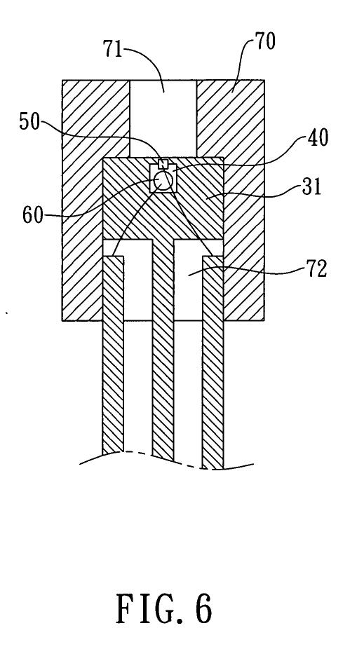

A transparent adhesive layer 60 is spread on the photo diode 40 on which the conducting wire is bonded for forming a convex lens. On the one hand, the transparent adhesive layer 60 may be separated from the conducting wires. On the other hand, for the purpose of protection, the adhesive layer may be formed on the conducting wires. Referring further to FIG. 5 and FIG. 6, the photo diode 40 and the laser diode 50 are covered from top to bottom with a casing 70 on which an opening 71, a notch 72, and a mounting chamber are formed for mounting the top ends of the pins, the photo diode 40, the laser diode 50, the conducting wires, and the transparent adhesive layer 60 in the mounting chamber of the casing 70. Thereafter, the connected portions of the frame 30 including the connected sections of the pins are cut off for obtaining the laser. Consequently, this manufacture method is suitable for mass production to obtain numerous lasers.

When the electric power is applied to the laser 50, the laser light is emitted from its front and rear ends simultaneously. The laser light, which is emitted from the front end, is emitted outward from the opening 71 of the casing 70. The laser light, which is emitted from the rear end, is refracted and collected by the convex transparent adhesive layer 60 for providing more laser light for the photo diode 40. Accordingly, the external circuit can be applied for feedback to prevent the photo diode from the inability to receive the feedback light from the laser diode.

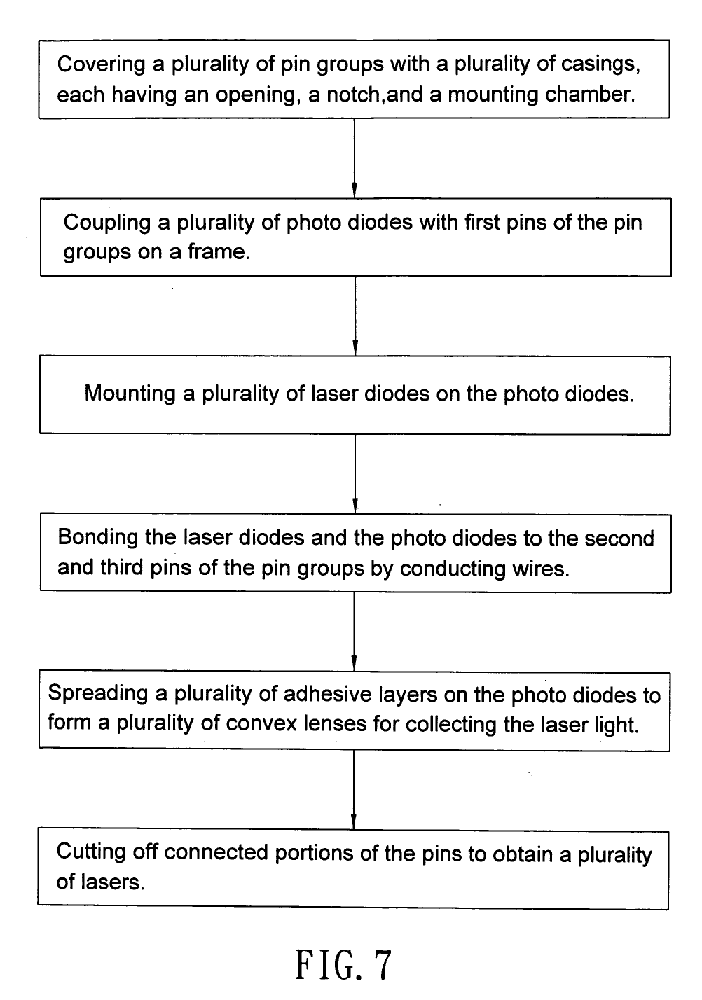

Referring further to FIG. 7, another manufacture process of the present invention comprises the steps of:

1. covering a plurality of pin groups with a plurality of casings, each having an opening, a notch, and a mounting chamber;

2. coupling a plurality of photo diodes with first pins of the pin groups on a frame;

3. mounting a plurality of laser diodes on the photo diodes;

4. bonding the laser diodes and the photo diodes to the second and third pins of the pin groups by conducting wires;

5. spreading a plurality of adhesive layers on the photo diodes to form a plurality of convex lenses for collecting the laser light; and

6. cutting off connected portions of the pins to obtain a plurality of lasers.

From the above-mentioned description, it is apparent that the manufacture method of the present invention has the following advantages in which:

1. The manufacture process of the present invention is simple, fast, and therefore suitable for mass production. Accordingly, it is able to significantly reduce the production cost, stabilize the laser quality, and increase the yield.

2. The convex lens is formed on the photo diode by forming a transparent adhesive layer on the photo-collecting region of the photo diode so as to receive the light, which is emitted from the rear end of the laser diode, for increasing the value of the monitor current (Im).

3. The transparent adhesive layer on the photo diode can protect the conducting wires for further promoting the credibility of the laser.

On the basis of the aforementioned description, the present invention discloses structure and manufacture method of the laser to improve the deficiency of the conventional laser in receiving the feedback light. Besides, the manufacture method of the present invention can simplify the manufacture process, reduce the production cost, increase the Im value, and increase the credibility. The present invention satisfies all requirements for a patent and is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A manufacture method of laser, comprising the steps of:
a. coupling a plurality of photo diodes with first pins of a plurality of pin groups on a frame;
b. mounting a plurality of laser diodes on the photo diodes;
c. bonding the laser diodes and the photo diodes to the second and third pins of the pin groups by conducting wires;
d. spreading a plurality of adhesive layers on the photo diodes to form a plurality of convex lenses for collecting laser light;
e. covering the pin groups on which the bonding and spreading steps are performed with a plurality of casings, each having an opening, a notch, and a mounting chamber; and
f. cutting off connected portions of the pins to obtain a plurality of lasers.

2. A structure of laser, comprising:
a frame having three pins, one of which having a large area connection part on the top;
a photo diode mounted on the large area connection part of the pin;
a laser diode mounted on the photo diode;
two conducting wires for connecting the photo diode and the laser diode with the rest of the three pins;
a transparent adhesive layer formed on the photo diode; and
a casing mounted on the top of the frame, the casing having an opening, a notch, a mounting chamber such that the light emitted from the front end of the laser diode is emitted outward through the opening and the light emitted from the rear end of the laser diode is refracted and collected by the transparent adhesive layer for use in the photo diode.

3. The structure of laser of the claim 2, wherein the transparent adhesive layer is separated from or connected with the conductive layers.

4. A manufacture method of laser, comprising the steps of:
a. covering a plurality of pin groups with a plurality of casings, each having an opening, a notch, and a mounting chamber;
b. coupling a plurality of photo diodes with first pins of the pin groups on a frame;
c. mounting a plurality of laser diodes on the photo diodes;
d. bonding the laser diodes and the photo diodes to the second and third pins of the pin groups by conducting wires;
e. spreading a plurality of adhesive layers on the photo diodes to form a plurality of convex lenses for collecting the laser light; and
f. cutting off connected portions of the pins to obtain a plurality of lasers.
